(19) United States
(12) Patent Application Publication
(10) Pub. No.: US 2024/0164034 A1
(43) Pub. Date: May 16, 2024

(54) SUPPORT DEVICE, IN PARTICULAR SHELF RAIL, FOR SUPPORTING AN ELECTRONIC DEVICE, PREFERABLY AN ELECTRONIC DISPLAY UNIT

(71) Applicant: SES-Imagotag GmbH, Fernitz-Mellach (AT)

(72) Inventor: Andreas RÖSSL, Fernitz-Mellach (AT)

(21) Appl. No.: 18/549,521

(22) PCT Filed: Mar. 9, 2021
(86) PCT No.: PCT/EP2021/055914

§ 371 Date: Sep. 7, 2023

(51) Int. Cl. H05K 5/02; H02G 5/02

(52) U.S. Cl. CPC H05K 5/0247; H02G 5/025

(57) ABSTRACT

A support device, preferably realized as shelf rail, for mechanically fastening an electronic device, particularly preferably for fastening an electronic display unit, wherein the support device comprises a first delimiting wall, in particular a reference wall defining a reference or positioning plane, respectively, on the or adjacent to which the electronic device can be positioned, in particular with its rear wall, on the support device, and a second delimiting wall, which is oriented at an angle to the first delimiting wall, wherein the first delimiting wall and the second delimiting wall delimit, in particular only on two sides, a receiving region for receiving the electronic device, and a conductor support, which supports conductor tracks for the electronic supply of the device, characterized in that the conductor support protrudes into the receiving region at a distance from the first delimiting wall, starting at the second delimiting wall, in particular parallel to the first delimiting wall.

### TECHNICAL FIELD

The invention relates to a support device, in particular shelf rail, for supporting an electronic device, preferably an electronic display unit, wherein the support device comprises delimiting walls for delimiting a receiving region for receiving the electronic device.

### BACKGROUND

WO 2017/153481 A1 discloses a support device in the form of a shelf rail (sometimes termed shelf edge stripe), which is formed for mechanically fastening an electronic device, realized as an electronic display unit. The shelf rail delimits a receiving region for receiving the display unit by means of three side walls arranged in U-shape. The receiving region is thus delimited on three sides here and the display unit can be inserted into the shelf rail or can be removed from there, respectively, via the side of the U-shape, which is left free.

A first, central side wall is formed by means of a plate. This plate serves as reference or positioning plane, respectively, on which the display unit can be positioned with its rear wall on the shelf rail. The plate has passages arranged in the grid. These passages serve for contacting electric conductor tracks by means of contact pins of the display unit in order to electrically supply the display unit. The conductor tracks are arranged on a conductor support, which is positioned on that side of the first side wall, which faces away from the receiving region.

Viewed in the longitudinal direction of the shelf rail, the first side wall is delimited by means of a second, upper side wall, and a third, lower side wall.

The lower side wall has a fastening edge, which runs in the longitudinal direction of the shelf rail and which can be encompassed by a fastening groove of the display means.

In the longitudinal direction of the shelf rail, the upper side wall has hole-like recesses, which are arranged in the grid and with which a retractable and extendable fastening pin of the display means can engage, whereby the position of the display device can be fixed along the shelf rail.

This shelf rail has proved excellently during operation because it allows for a precise positioning of the display means along the shelf rail according to the grid of the hole-like recesses, and makes an unintentional shifting and even an unintentional or also intentional removal of the display unit from the shelf rail without destructive force largely impossible by means of the second and the third side wall in combination with the pin, which is extended and which is engaged with the upper side wall.

However, the maintenance of the shelf rail has proved problematic because contaminations can deposit in the chamfer formed by the lower side wall between the central plate and the fastening edge as well as in the passages of the central plate towards the conductor tracks. On the one hand, these contaminations have a negative impact on the optical appearance of the shelf rail. On the other hand, they can also impair the electrical supply of the display unit and thus the functional reliability thereof.

It is thus the object of the invention to provide an improved support device and a correspondingly adapted electronic device, so that the discussed problems are avoided.

### SUMMARY OF THE INVENTION

This object is solved by means of a support device according to claim 1. The subject matter of the invention is thus a support device, preferably realized as shelf rail (sometimes termed shelf edge stripe), for mechanically fastening an electronic device, particularly preferably for fastening an electronic display unit, wherein the support device comprises a first delimiting wall, in particular a reference wall defining a reference or positioning plane, respectively, on the or adjacent to which the electronic device can be positioned, in particular with its rear wall, on the support device, and a second delimiting wall, which is oriented at an angle to the first delimiting wall, wherein the first delimiting wall and the second delimiting wall delimit, in particular only on two sides, a receiving region for receiving the electronic device, and a conductor support, which supports conductor tracks for the electronic supply of the device, characterized in that the conductor support protrudes into the receiving region at a distance from the first delimiting wall, starting at the second delimiting wall, in particular parallel to the first delimiting wall.

This object is furthermore solved by means of a supply means according to claim 16. The subject matter of the invention is thus a supply means for a support device, in particular realized as shelf rail, for the electric supply of an electronic device, which can be supported by means of the support device, particularly preferably of an electronic display unit, wherein the supply means is formed in such a way that it can be coupled to a side or end portion, respectively, of the support device, which side or end portion, respectively, is formed or provided, respectively, for receiving the supply means, wherein the supply means comprises: a supply electronics and contacts connected to the supply electronics for establishing an electrically conductive connection with conductor tracks arranged on a conductor support of the support device, characterized in that the contacts are realized by means of a first group of metallic contact bands, wherein each contact band comprises a first portion, preferably first end portion, which first portion is connected to the supply electronics, and comprises a second portion, preferably second end portion, which second portion is intended for contacting the conductor tracks of the conductor support, and wherein each contact band is formed in a curved or angled manner, preferably at least in an L-shaped, particularly preferably in a C- or U-shaped manner, respectively.

This object is furthermore solved by means of an electronic device according to claim 19. The subject matter of invention is thus an electronic device, in particular electronic display unit, which comprises a housing comprising a rear wall, a front wall, in particular comprising a screen, and a side wall running between the rear wall and the front wall, wherein the side wall comprises a conductor support groove, which runs essentially parallel to the rear wall, and which is intended for receiving a conductor support of a support device, wherein the conductor support comprises conductor tracks for the electronic supply of the electronic device, in particular of the display unit.

This object is furthermore solved by means of a system according to claim 29. The subject matter of the invention is thus a system, which comprises a support device according to the invention, a supply means according to the invention, which is coupled thereto, and at least one electronic device according to the invention, which is supported by means of the support device.

The measures according to the invention are associated with the advantage that the insertion of an electronic device is much easier. Due to the elimination associated with the measures according to the invention of the fastening edge of the lower side wall, which comprises the known shelf rail, the electronic device can be pushed easily into the support device, without tilting movements. This means that the electronic device can be moved in an insertable manner along the first delimiting wall, which can hereby also act as reference wall, towards the second delimiting wall, in particular so that the electronic device, which is to be inserted, does not need to be lifted off the first delimiting wall.

This applies in an equivalent manner for the removal of the electronic device.

Due to the elimination of the disadvantageous formation of the prior art, thus due to the elimination of the (lower) fastening edge (in the case of horizontal mounting of the shelf rail) and thus also of the chamfer, this is furthermore associated with the advantage that dirt in the form of solid or liquid substances can no longer accumulate at this point. The optical impairments as well as functional interferences resulting therefrom are thus de facto ruled out.

Due to the displacement of the conductor tracks of the conductor support into a region within the receiving region, which is, after all, cased or delimited, respectively, by the two delimiting walls, it is also largely ensured that the conductor tracks can hardly or not at all contaminate there. The same applies analogously for the conductor support groove of the electronic device, which is provided for receiving the conductor support, where the contacts of the electronic device are located. This is so because this conductor support groove is covered, thus protected, by means of the second delimiting wall of the support device when the device is inserted into the support device.

The maintenance intensity of the support device, in particular realized as shelf rail, or of the entire system, respectively, can thus be reduced significantly by means of the measures according to the invention. Cleaning becomes easier and is necessary less frequently because the point in the formation according to the invention, which is critical with respect to dirt, is on both sides or is now arranged and formed so that the risk of a contamination is minimized, if possible.

In the preferred case, the orientation of the conductor support with respect to the first delimiting wall, is parallel to the latter. However, another orientation can also be provided. The conductor support can thus also be oriented, e.g., so that viewed starting at the second delimiting wall, the distance thereof from the first delimiting wall increases continuously. In the receiving region, the conductor support is then oriented so as to slant slightly forward in the direction of the open sides (which are thus not delimited by the delimiting walls) of the receiving region. The orientation of the conductor support groove with respect to the rear wall of the electronic device can also be adapted accordingly in this case, so that the electronic device can be inserted into the receiving region so as to slide along the conductor support towards the first delimiting wall.

In the case of the first delimiting wall, the rear side of this first delimiting wall also does not have to mandatorily run parallel to the front side of the first delimiting wall. On the contrary, it can also be provided that the front side and the rear side of the first delimiting wall are oriented so as to converge towards one another in a wedge-shaped manner in the viewing direction towards the second delimiting wall. The cross section of the first delimiting wall can thus also be realized in an essentially wedge-shaped manner. A differentiation can thus be made between the rear side of the delimiting wall and a front side of the delimiting wall (e.g. referred to as reference side), which is inclined with respect thereto. As already mentioned, the orientation of the conductor support in this case can also be oriented either parallel to the front side of the delimiting wall or inclined away from it at an angle, wherein, in the latter case, the orientation of the conductor support groove would need to be adapted accordingly again, as discussed above.

It would likewise also be possible not to adapt the orientation of the conductor support groove, but to leave it essentially parallel to the front side of the electronic device or to also let it run centrally between the front side and the rear side of the electronic device, and to adapt the orientation of the rear wall of the electronic device, in order to attain an essential positive fit of the electronic device, which is inserted into the support device.

Due to the fact that the electronic device is accessible from the bottom on the shelf rail, e.g. on a horizontally running shelf rail, the entire handling is also made easier.

The measures according to the invention are furthermore associated with the advantage that the support device becomes more compact and the field of view onto objects, in particular goods, located behind it is enlarged. In the case of a support device according to the invention, designed, for example, as shelf rail, a customer can thus, for example, easily inspect the products in the shelf below the shelf rail, without being prevented from doing so by means of structural elements of the shelf rail, which protrude downward.

These measures according to the invention generally provide for a freer and lighter appearance of the system, specifically of the support device and of the electronic devices fastened thereto, in particular of the electronic display units, and thus provide for an improved presentation of the goods.

The measures according to the invention and the associated elimination of the lower fastening edge furthermore provides for the use of electronic devices, which, parallel to the first delimiting wall (reference wall), can comprise an expansion, which slightly exceeds, optionally also massively exceeds, that of the first delimiting wall. Compared to the display units, the shelf rail as such can thus turn out to be slimmer, which automatically draws attention to the display units, without the shelf rail being perceived as massive, optically distracting element. The elimination of the lower fastening edge thus provides for the use of electronic devices with virtually any dimension parallel to the first delimiting wall or to the reference wall, respectively. Virtually every electronic device can thus also be adapted for the use with such a support device. In particular, electronic display units with highly specific and most varied screen dimensions as well as large-area electronic interaction media, such as, e.g., touchscreens, etc., can thus be used. These devices appear to the observer as being suspended in the support device, because they protrude the support device on its, e.g., lower side.

The support device can generally be realized in a diverse manner. It can thus be, for example, a table display, which can be set up on a counter or can be fixed there. It is likewise possible to form the support structure as clothing tag, which can be fixed to clothing, hanging on it. In the interest of a compact description of the invention, however, reference will be made below exclusively to a shelf rail as preferred embodiment of the support device.

The orientation of the support device and thus also the orientation of the devices fastened to it, can also be arbitrary.

The electrically conductive connection between supply means and support device can be realized in a conditionally detachable or non-detachable manner, thus in particular by means of a substance-to-substance bond, e.g., by means of solder connections.

It is advantageous in many cases when the electrically conductive connection can be easily separated again. Such a connection can be realized by means of detachable connections, such as plug connections or screw connections, etc., among others.

The electrically conductive connection is preferably realized as detachable connection, which comprises a spring element. Such a spring element ensures that the electrical contact is preserved with a minimal force within a certain range even in the case of positional changes of the component parts to be connected. Such a positional change may be or can be caused, respectively, by means of, for example, manufacturing tolerances, thermal expansion, wear-related deformation, inaccurate assembly of the components, or mechanical stressing of the system components.

The supply means preferably comprises the first group of metallic contact bands, thus electrically conductive metal contact bands. These contact bands are formed for providing the electrically conductive connection with the support device or with the conductor tracks of the support device, respectively.

These contact bands can be formed for the realization of a non-detachable contact, such as, for example, substance-to-substance bond, or detachable contact.

In the case of an embodiment for a contact by means of plug connection, the contact bands are embodied so that, when the supply means is inserted into the support device, the contact bands are guided towards the conductor tracks. For this purpose, the surrounding area of the conductor tracks is formed so that a yielding of the contact bands away from the conductor tracks is prevented. The secure contacting results due to local deformation in the elastic region.

To realize a non-detachable contact, in particular by means of substance-to-substance bond, the contact bands can be embodied so that, in the inserted state of the support device, they are in contact with the conductor tracks, whereupon they can be soldered, for example.

However, a detachable spring-based connection is preferably used, thus a connection, which comprises a spring element. In this case, the contact bands are embodied so that, when the supply means is inserted into the support device, said contact bands are pushed against the conductor tracks by means of a spring force. In contrast to a plug connection, the force that ensures the contacting is thus not or not only generated locally, respectively, by means of deformation at the contact point, but also or in particular, respectively, by means of deformation, for example, bending, at a point, which is not the contact point, or along the contact band.

The contact bands themselves particularly preferably form the spring elements. They are thus embodied as supply spring contact elements.

As mentioned, the contact bands comprise a first portion, preferably a first end portion, which is connected to the supply electronics. The contact bands furthermore comprise a second portion, preferably second end portion, which is formed for providing the electrically conductive connection or the contact, respectively.

The contact bands can be formed in various shapes, for example, the arrangement of the first and second portion can be embodied differently.

In a simple embodiment, the contact band can thus be embodied in a rod-shaped manner, so that the first and second portion essentially lie on one plane along the rod surface.

It is also possible that the two portions are formed slightly offset, but essentially parallel to one another, this comprising one step or several steps, or in a z-shaped manner, respectively.

It is also possible that both portions are arranged at an angle relative to one another, so that an L-shape or a V-shape, respectively, is created.

It is also possible that both portions are arranged essentially parallel to one another, but with several angled portion in between, so that a C-shape or U-shape, respectively, or a W-shape is created.

In addition to the mentioned embodiments, further multi-step embodiments of the portions are also possible, so that, for example, meander-shaped contact bands are created.

The angled and multi-step embodiments have the advantage that a larger spring deflection with simultaneously lower material stress is possible, which is why they represent the preferred embodiments. This can also be realized with a curved shape of the metallic contact bands.

The band-shaped embodiment of the contact bands furthermore makes it possible to guide or shape them, respectively, so that level differences between the electronics, to which they are connected, and the plane of the conductor tracks, which are to be contacted, are overcome without any problems. This is also associated with the effect that the contacting can take place with a predefined minimal force (but also maximal force, thus within a range of the appearing force), which can be set or defined, respectively, by means of the shaping and the elastic properties of the material of the contact bands.

Corrosion-resistant steel bands are preferably used.

In spite of mobility of the contact surfaces or zones, respectively, mechanical individual components, which are complicated, in particular movable relative to one another, are thus forgone.

Further, particularly advantageous designs and further developments of the invention follow from the dependent claims as well as the following description.

A non-exhaustive enumeration of examples for electronic devices includes sensor units or sensors, respectively, such as motion sensors, temperature sensors, light sensors and cameras, input devices, such as buttons, touch sensors, touch screens, output devices such as lighting, loudspeakers, printers, e.g. thermal printers, or electronic display units, such as, for example, embodied by means of liquid crystal display (LCD) screens, organic light emitting diodes (OLED) screens, etc., or e-paper displays or electrophoretic displays, respectively.

The supply means supplies the electronic devices with the necessary supply voltage for operating said electronic devices as well as in terms of communication technology. In addition to the power supply (supply voltage and current) it thus also takes over the supply in terms of data or signaling technology, respectively, for the purpose of transferring information as well as control of the electronic device or devices, respectively. For the purpose of power supply, the supply means can be supplied by means of a power supply unit, comprising a (re-chargeable) battery configuration or by means of “power over WiFi”. In the case of an (also re-chargeable) battery or also of an accumulator, this energy storage can preferably be fastened with the help of magnets to the support device or an adjacent component part in the immediate vicinity of the supply means, in order to provide for a quick and uncomplicated replacement. The support device can also be equipped with a photovoltaic module, which is used for gathering energy for the purpose of storage in a re-chargeable battery.

The supply means or the supply electronics, respectively, of the supply means can furthermore be formed to process or to prepare data, thus for example receive data from a server via an access point, and to convert them into signals or data, respectively, which can be read or processed, respectively, by the electronic device, or to simply transfer them to the relevant (addressed) devices as raw data. Data can also be received by the devices and can be output to the server via the access point. These transfers between the access point and the supply means can take place in a wired or radio-based manner.

The supply means can be placed independently of the support device or, behind the support device or on one side of the support device, can be fastened to the latter and can be connected in an electrically conductive manner to the conductor tracks of the conductor support of the support device.

It has turned out to be particularly advantageous in this context when the support device comprises a side portion, which is formed or provided, respectively, for receiving the supply means for the purpose of the electrical supply of electronic devices, which can be supported by means of the support device.

The supply means is therefore preferably formed in order to be received in the side portion of the support device.

A very compact system is thus created, wherein the supply means is simultaneously received in the structure of the support device so as to be protected against environmental influences, such as, e.g., moisture or mechanical stress.

Loose cabling between the supply means and the support device can thus neither be accessed nor manipulated.

A full integration of a separate supply means into the rail is preferred, wherein, e.g., a housing of the supply means is also adapted to the shape of the support device in this case, so that together, they both create the impression as if they were cast from the same mold.

It has furthermore proved advantageous when each contact band comprises, on its second portion, an arc shape, which is provided for the direct contact with one of the conductor tracks.

This arc shape prevents that the second portion of the contact bands wedges or gets caught, respectively, during the insertion of the supply means into the support device. In the case of careless or quick insertion, respectively, such a wedging or getting caught, respectively, could lead to damages to the components, for example to the deformation of the contact bands or also of the conductor tracks. The arc shape thus allows for a quicker and economical assembly and maintenance of the system without the mentioned risks.

An improved contact is also associated with this shape, because a defined contact surface or zone, respectively, along the metal band is thus created by means of the radius of curvature of the arc shape.

To optimize the contact between the conductor track and the contact band, the arc shape of the second portion can comprise a contacting region, which is adapted to the shape of the conductor track. In the case of circular conductor track cross sections, the surface of the arc shape can thus comprise, for example, a corresponding semi-circular notch or groove, respectively, which is adapted to the conductor track, so that the contact surface or zone, respectively, is enlarged along the curvature of the conductor track.

According to a further aspect, the supply means comprises a housing part, which is open at least on one side, so that the conductor support can be inserted on the open housing side, wherein the housing part is shaped in such a way that the second portions of the contact bands and the part of the conductor tracks that can be contacted therewith, thus the affected part of the conductor support, are encompassed.

This embodiment offers protection for the cased contact bands and conductor tracks. It provides protection in particular against touch, moisture, mechanical stress, thermal stress, and unwanted visibility of the components, thus visual protection.

The housing part additionally ensures a defined positioning of the contact bands relative to the conductor tracks. For this purpose, the housing comprises portions or surfaces, at which the housing part cooperates with the support device and is positioned or held there accordingly, respectively.

The housing part simultaneously gives stability to the supply means and provides the structure for holding all of the components of the supply means at their target position.

The housing part can be formed so that it initially covers or receives, respectively, a part of the conductor support. In the assembled state, this measure additionally makes unauthorized manipulation to the electronic components of the system more difficult. If the housing is also in contact with the conductor support, this measure ensures the mechanical stability at that point, where the metallic contact bands push with their force, which is caused by the spring effect, against the conductor tracks and, as a result, against the conductor support.

The conductor support of the support device can be embodied in one piece or in several pieces. In both cases, it is possible that the conductor tracks lie in one or in several planes, wherein the contact bands of the supply means have to be designed or arranged accordingly, respectively, in order to contact the conductor tracks.

It has proved particularly advantageous, however, when the conductor support of the support device is formed as conductor support plate.

This represents a highly space-saving, slim, and simultaneously stable embodiment and leaves sufficient space for the conductor tracks. At the conductor support plate, the conductor tracks can be positioned on one side of the plate or on different sides. Above all, the conductor support plate provides the advantage that the conductor tracks can run along the conductor support plate, e.g., in one plane, with sufficient distance from one another.

In the case of proper use of the system, the use of a conductor support plate provides defined contact points or zones, respectively, to the electronic device, where the conductor support or the conductor support plate, respectively, is in contact with the electronic device. In particular when completely inserted into the conductor support groove of the device, the position of the device is exactly defined, which manifests itself in particular in the form of a reliable electronic contacting.

According to a further aspect, the conductor support plate comprises a first dimension, which is measured along the longitudinal extension of the support device, and comprises a second dimension, which, in the plane of the conductor support plate, is measured in a normal manner at the first dimension of the conductor support plate, wherein the second dimension of the conductor support plate corresponds to 20% to 40% of the corresponding dimension of the first delimiting wall.

It is attained thereby that the conductor support plate is embodied in a sufficiently stable and stiff manner, while a sufficient distance between the conductor tracks is simultaneously also ensured.

These dimension ratios furthermore provide for a simple removal of the electronic devices from the support device and for a simple insertion or positioning, respectively, of the electronic devices in the support device, because a spatial guidance for the movement of the device is established during the insertion into the support device or during the withdrawal from the support device, respectively, by means of the dimension of the conductor support plate.

Due to the fact that a sufficient stability and stiffness is present in the case of these dimensions when using the common materials and material thicknesses, incorrect positions of the conductor support plate with respect to the first delimiting wall can be reliably avoided, whereby a shifting or offsetting, respectively, of the electronic devices along the support device without jamming is also ensured.

The first dimension preferably extends over the entire length of the support device, so that the devices can also be supplied along the entire length.

The conductor support can comprise several conductor tracks for the supply in terms of signaling technology and several, in particular two, conductor tracks for the power supply. E.g., one pair of the conductor tracks can thus serve for the electric power supply, and additional, e.g., ten, conductor tracks, can realize a data bus for the bidirectional parallel information transfer.

However, the conductor support preferably comprises exactly three pieces of the conductor tracks, which are preferably formed at a single side surface of the conductor support and/or which run parallel to one another along the longitudinal extension of the support device.

This embodiment allows for a supply in terms of signaling technology as well as for a power supply with as few components as possible, in particular contact components, such as, concretely, the contact bands. A compact and space-saving realization is thus made possible.

The few components also make this realization less susceptible to malfunctions, which, as a result, increases the operational safety and therefore reduces the total maintenance effort. This is also associated with a cost-efficient production.

The embodiment of the conductor support with exactly three pieces of the conductor tracks can be realized in that the signal or data supply line, respectively, which represents one of the conductor tracks, as well as the power supply line, which represents an additional conductor track, use the same reference potential, wherein the third conductor track, here also referred to as reference potential line, has this reference potential.

With respect to the insertion direction of the electronic device, the conductor tracks are particularly preferably arranged so that firstly the ground line, then the signal or data supply line, respectively, and finally the power supply line is arranged. The circuit between power supply line and ground line is thus only at hand in the completely inserted state, which avoids short-circuits and damages to the electronic components.

The conductor tracks of the support device can have different shapes or cross sections, respectively.

According to an embodiment, these conductor tracks can be flat or can have a square cross section, respectively. This embodiment provides the advantage that in the case of spring-based connections, a large line cross section at the contact points is ensured. Flat conductor tracks can be realized easily as tracks on the support plate, e.g. similarly as in the case of printed circuit boards.

According to a preferred embodiment, however, the conductor tracks are embodied as wires, which partially protrude beyond the outer surface of the conductor support.

In addition to the production-related advantages, this embodiment provides advantages with respect to the electrical contacting with the electronic devices.

This takes effect in particular when, according to a preferred embodiment, the electronic device, in particular the electronic display unit, comprises contacts for establishing an electrically conductive connection with the conductor tracks of the conductor support, wherein that housing part, which forms the conductor support groove, comprises first housing openings, through which the contacts protrude out of the housing.

The conductor support groove allows for a clearly defined positioning of the electronic device and the contacts thereof with respect to the conductor tracks, so that the contacts automatically form an electrically conductive connection with the conductor tracks in a reliable manner and without additional adjustment, as soon as the device is fastened to the support device, thus the conductor support is positioned in its target position in the conductor support groove.

Wires as conductor tracks have an essentially round cross section, which protrudes in a raised manner beyond the surface of the conductor support. In contrast to a flat cross section, which is essentially flush with the surface of the conductor support, this cross section allows for a tactile response during the insertion of the electronic device, as soon as one of the contacts of the electronic device touches one of the wires. The user can thus easily determine whether the respective contact of the device has already reached or passed, respectively, the conductor support.

In contrast to, for example, flat conductor tracks, wires as conductor tracks furthermore impress due to their robustness.

The wires are preferably located in the conductor support with at least 50% of their cross section. In the case of this embodiment, a secure hold is at hand in the conductor support, because the conductor support encompasses the respective wire at least with slightly more than 180° on the circumference. The conductor track is thus reliably prevented from unintentionally falling out of the conductor support.

The conductor tracks can be arranged at the conductor support so that they are arranged on that side of the conductor support, which faces away from the first delimiting wall or the reference wall, respectively.

However, the support device is preferably formed so that the conductor tracks are arranged on that side of the conductor support, which faces the first delimiting wall or the reference wall, respectively.

The electronic device is therefore preferably formed so that the first housing openings are realized on that side of the conductor support groove, which is closest to the rear wall.

The measures of these preferred embodiments are associated with the advantage that the conductor tracks can only be accessed with difficulty, if not at all, and an inadvertent or intentional touching, in particular with a conductive object, is virtually ruled out. As a result, the risk of a short-circuit or of a transmission interference is also reduced or completely ruled out. This arrangement of the conductor tracks, which is essentially hidden from the view of an observer of the support device (e.g. a shelf rail) moreover provides an extensive protection against contamination, so that a corresponding maintenance effort is negligible.

According to a further aspect, the electronic device is formed so that one of the housing openings in each case corresponds to the position of exactly one of the conductor tracks, when the conductor support is inserted into the conductor support groove as intended.

This ensures that when assembling the devices with the support device, exactly defined contacting zones are always present, which lead to a precise contacting of the conductor tracks in the end or target position, respectively. When the insertion of the electronic device into the support device has been completed, correct electrical connections result inevitably, without requiring a readjusting or correcting of the relative position of the two objects.

According to a further aspect, the contacts of the electronic devices are realized as a second group of metallic contact bands, wherein each contact band comprises a first portion, preferably first end portion, which first portion is connected to a device electronics, and comprises a second portion, preferably second end portion, which second portion is intended for contacting the conductor tracks of the conductor support, wherein the second group of metallic contact bands is embodied as spring elements, wherein each contact band is preferably formed in a curved or angled manner, in particular in a step-shaped manner.

This allows for a pressurized contacting. The advantages mentioned in the context of the first group of metallic contact bands in the case of an embodiment as spring-based electrically conductive connection, thus also take effect here. For example, angular errors and offsets of the contact surfaces can thus also be compensated here.

The contacts known from the prior art, in the case of which a helical spring pushes the pin-shaped contact against the counter contact in a linear movement, turned out to be disadvantageous not only due to their many components, but also due to their susceptibility to failure, in particular in the case of contamination.

Disadvantages of the telescopic spring contacts are overcome by means of the embodiment of the second group of metallic contact bands as (essentially one-piece) spring elements. Dirt particles, such as, for example, grains or dust, or also viscid liquids, which can be sufficient in the case of these known systems to cause malfunctions, have no negative impact whatsoever on the embodiment according to the invention.

If the contact bands according to a preferred embodiment are formed in a curved or angled manner, in particular in a step-shaped manner, this furthermore increases the spring deflection, which additionally decreases the risk of wedging or jamming, respectively, as a result of dirt or wear.

The band-shaped formation of the contact bands furthermore makes it possible to guide or to shape them, respectively, so that level differences between the electronics, to which they are connected, and the plane of the conductor tracks, which are to be contacted, are overcome without any problems. This is also associated with the effect that the contacting can take place with a predefined minimal force (but also maximal force, thus within a range of the appearing force), which can be set or defined, respectively, by means of the shaping and the elastic properties of the material of the contact bands.

Corrosion-resistant steel bands are preferably used.

In spite of the mobility of the contact surfaces or zones, respectively, mechanical individual components, which are complicated, in particular movable relatively to one another, are thus forgone.

According to a preferred embodiment of the electronic device, in particular of the electronic display unit, each contact band of the second group comprises on its second portion a raised shape, which is provided for the direct contact with one of the conductor tracks, and at least the raised shape of the contact band emerges from the housing at the assigned housing opening and protrudes into the spatial region delimited by the conductor support groove.

This raised shape makes it possible for each contact band to securely contact only a single conductor track in each case essentially accurately at the point of the raised shape, wherein adjacent regions of the contact band simultaneously run at a distance from the conductor track or conductor tracks, respectively, thus run in a contact-free manner to the conductor track or conductor tracks, respectively.

The raised shape is preferably rounded at that side, which, in the assembled state, is in contact with a conductor track.

This raised shape has the result that the electronic device can be inserted into the support device without wedging and with virtually no wear. During the insertion, the second portion of the contact bands initially slides along the surface of the conductor support, until it reaches a conductor track. Once arrived there, the second portion of the contact bands follows the cross sectional shape of the conductor track during the further insertion without wedging or scraping the conductor track.

This raised shape can be realized, for example, in that the contact band is arcuate at the respective point, so that it comprises, for example, an arc, which represents the raised shape. The raised shape, however, can also take place, for example, by applying additional material to an otherwise linear second portion of the contact band. The desired shape, however, can also be created by means of other shaping methods, so that, for example, a lug shape is forced upon a second portion consisting of sheet metal by means of a punch.

The shaping of the contact bands can take place in an equivalent manner for the electronic device as well as for the supply means.

The conductor support of the support device can be connected by means of a substance-to-substance bond to the second delimiting wall of the support device. These components can thus, for example, be welded or adhered together

Together, the conductor support and the second delimiting wall can also be made of a single material. It can thus be, for example, a cast part.

The conductor support and the second delimiting wall can furthermore be screwed or riveted together.

The conductor support can also be connected to the support device by means of a plug connection, in particular by means of plug connections comprising barbs.

It has proved particularly advantageous, however, when the second delimiting wall of the support device comprises a receiving shaft, which is provided for receiving, in particular for laterally insertable receiving, the conductor support, and the conductor support comprises a shape, which corresponds to the shape of the receiving shaft, in particular a T-shape or an upside down L-shape, etc., and is inserted into the receiving shaft. This simultaneously allows for a simple assembly of the conductor support with the support structure and simultaneously provides good stability. The conductor support can thus also be removed easily for maintenance or cleaning. The conductor support can thus also be replaced in a modular manner as replacement part. In the case of damage, for example, the entire support device thus does not need to be replaced.

According to a further aspect, the second delimiting wall of the support device can comprise a support web, which extends essentially along the longitudinal extension of the conductor support and mechanically supports the latter.

This support web makes it possible to design the conductor support to be less stable, which makes it possible, on the one hand, to resort to more cost-efficient materials, and which makes it possible, on the other hand, to realize a narrower appearance of the conductor support or to also simply realize the conductor support in a more material-saving manner.

Longer alternatives of the support device can also be realized by means of the mechanical reinforcement. The support web furthermore counteracts damages to the conductor support during the mounting or during the operation. The protection of the conductor support is also associated with an increased protection of the conductor bands, because the conductor support is optionally affected negatively or deformed to a lesser extent, respectively, under the impact of bending moments.

The support web can be made, for example, of plastic or preferably of metal.

According to an embodiment, the support web is formed to be received next to the conductor support in the receiving shaft of the second delimiting wall, wherein the second delimiting wall is accordingly formed to receive the conductor support and the support web jointly. For this purpose, the support web can have, for example, a T-shape at the corresponding end, which is inserted into the receiving shaft, and the conductor support can have an L-shape, which is fastened on a side of the T-shape of the support web in the receiving shaft.

The conductor support is preferably made of plastic.

This provides for the embodiment of the conductor tracks, in particular embodied as wire, without additional insulating layer. The conductor support itself is the insulator here. The production is furthermore cost-efficient and the weight is low. Plastic is to hereby also be understood as a synonym for macromolecules, so that natural macromolecular substances are also included. The conductor support can furthermore be made of fiber-reinforced plastic or hard paper.

The first delimiting wall or the reference wall, respectively, and the second delimiting wall can likewise be made of plastic.

These parts can be manufactured individually and can be connected to one another in the already discussed manners.

It has proved particularly advantageous, however, when the first delimiting wall or the reference wall, respectively, and the second delimiting wall, in particular also the support web, are formed in one piece, in particular made of steel.

An optimal stiffness of the support device is thus possible, which, as a result, also ensures a clearly defined position of the contacting, also under stress or in particular in the case of relatively long longitudinal extension of the support device. In particular when the support web is also embodied in one piece together with the first delimiting wall or the reference wall, respectively, and the second delimiting wall, the conductor support is supported in a stable manner over the entire length. Damage as well as contact loss are thus avoided by means of the conductor tracks.

This can be realized particularly well when these components are made of steel, in particular of bent and possibly welded sheets. This embodiment does not only offer sufficient stability, but also provides for a simple and cost-efficient manufacture.

In most cases, the electronic device has to be coupled to the support device in order to prevent an unwanted falling out or removal. This can be attained, for example, in that the dimensions of the support device and the dimensions of the electronic device are selected so that in the assembled state, they are connected to one another in a non-positive manner. For this purpose, the conductor support and the first delimiting wall or the reference wall, respectively, can be dimensioned, for example, so that they exert a pressure on the inserted electronic device, which holds said electronic device in the desired position as a result of friction.

According to a preferred embodiment, however, the first delimiting wall or the reference wall, respectively, of the support device comprises recesses, which are arranged along its longitudinal extension in the grid, in particular openings, which pass through the first delimiting wall or the reference wall, respectively, and which are intended for the non-positive and/or positive coupling with fastening means of an electronic device.

Such fastening means can be realized so that the electronic device comprises fastening housing openings on the rear wall, and comprises a, preferably manually actuatable, fastening mechanism. The fastening mechanism comprises at least two movable fastening hooks or lugs, which, in the non-actuated state, protrude out through the fastening housing opening and change their position in response to actuation of the fastening mechanism.

The recesses can thereby be significantly wider than the fastening hooks or lugs, which allows for a continuous positioning of the electronic device along the support device in broad regions.

The recesses are preferably approximately as wide as the fastening hooks or fastening lugs, respectively. This allows for an exact positioning of the electronic devices along the support device in the grid dimension. It also simplifies the positioning of several electronic devices at equal distances along the support device. For example, a quicker equipment of a shelf with electronic displays and other electronic devices is thus possible, because it does not need to be remeasured whether the devices are positioned evenly.

A relatively fine grid additionally provides for a finely stepped positioning, thus provides a similar amount of design freedom as the continuous alternatively, while an exact positioning while maintaining defined minimal distances is possible at the same time without a remeasuring.

The grid, which is relatively fine and which extends essentially over the entire length of the support device, in particular ensures that the devices fastened there cannot be unintentionally shifted along the support device.

It additionally proved particularly advantageous when the grid or the dimension, respectively, of the recesses are dimensioned and are adapted to the dimensions or arrangement, respectively, of the fastening hooks or lugs so that devices with a different width (measured in the direction of the longitudinal extension of the support device) can be positioned as closely as possible against the support device, so as to be able to optimally utilize the equipping region, which is available there.

The fastening mechanism of the electronic device, in particular of the electronic display unit, preferably comprises a manually actuatable button, which is coupled to the fastening hooks or lugs, particularly preferably formed in one piece with the fastening hooks or lugs, and which is freely accessible at that side wall, which is located opposite the longitudinal support groove.

Such a button allows for a simple operation and quick removal of the electronic devices. This is associated with a quick and simple maintenance or carrying of the devices. Here, the removal is possible in particular without special tool.

Depending on the embodiment, the operation of the button can result in that the fastening hooks or lugs fold into the electronic device, shift in the insertion direction, or both. In all cases, the actuation of the button and the movement of the fastening hooks or lugs associated therewith results in that the electronic device can be removed from the support device.

A one-piece formation of the fastening means of the device combines the fastening hooks or lugs and the button, wherein the fastening hooks or lugs engage directly with the recesses.

In contrast, a two-piece or multi-piece embodiment of the fastening means of the device can be realized so that the rearward housing wall comprises the fastening hooks or lugs, which are arranged in the grid (or in the multiple of the grid dimension) of the recesses. The rearward housing wall is in particular formed in one piece with the (in particular two piece) fastening hooks or lugs (arranged at the grid distance or according to a multiple of the grid distance). The mentioned fastening housing openings are thereby formed by means of a U-shaped gap, which delimits the fastening hooks or lugs, which are formed as housing wall web.

In the rest position, which is relaxed in terms of force, the fastening hooks or lugs protrude into the recesses of the support device to the extent that the device is held there. Two fastening hooks or lugs are preferably provided, which are arranged at a sufficient distance with respect to the center of the rearward housing wall to the left side on the one hand, and to the right side on the other hand, of the rearward housing wall.

For the purpose of releasing the electronic device from the support device, the button can comprise a number of actuating appendages, which corresponds to the number of the fastening hooks or lugs and which are positioned so as to correspond to the positions thereof. These actuating appendages are shaped so that, in response to actuation of the button, they effect a pivoting of the fastening hooks or lugs in the direction of the housing interior of the device, so that the device can be removed from the support device. As soon as the button is released, the fastening hooks or lugs pivot into their rest position again on the basis of the elasticity of the housing material and/or of the elasticity of the fastening hook or fastening lug material, respectively, and/or of a correspondingly acting spring.

To promote the cooperation of the fastening hooks or lugs and of the actuating appendages, they can comprise beveled ends, so that their ends can de facto slide past one another along an inclined plane and thereby exert force on one another, which leads to the movement of the fastening hooks or lugs.

According to a preferred embodiment, the fastening mechanism comprises a fastening mechanism spring element, which, in the non-actuated state, holds the button in a first position.

The non-actuated state thereby refers to that state, in which the electronic device sits in the support device in accordance with the invention, is thus not inserted or removed at that very moment. With respect to the button, the non-actuated state means that the button is not pushed.

This fastening mechanism spring element does not only ensure a simple operation, but also ensures that, for the purpose of removal of the device from the support device, a targeted force on the button has to be present, which is so strong that the spring force, optionally together with a frictional force component, is overcome. An unintentional release of the device out of the support device is thus prevented by means of, e.g., lateral force on the housing, thus not on the button.

According to a preferred embodiment, the support device is formed so that, with respect to that side of the first delimiting wall, which is oriented towards the receiving region, an acute angle, in particular an angle in a range of from 35° to 85°, is formed between the first delimiting wall (or the reference wall, respectively, or the reference side) and the second delimiting wall.

It is ensured by means of the acute angle that the device can no longer fall forward or downward out of the support device as soon as the electronic device is braced in the support device by means of the fastening mechanism.

The second delimiting wall preferably comprises an edge region, which runs along the longitudinal extension and which is oriented towards the receiving region, preferably formed in a lug-shaped or hook-shaped manner, respectively, particularly preferably formed in an arcuate manner.

This means that the second delimiting wall comprises an edge region, which, in the case of use as intended, supports that edge of the electronic device, which, in the inserted state, is closest to the second delimiting wall, to the front. In this context, “to the front” refers to the direction from the first delimiting wall to the electronic device. The edge region thus seizes the electronic device on a front housing edge and holds it there in a protected manner below the second delimiting wall.

The acute angle makes it possible to seize the outermost, upper edge of the device, and to brace the device, held there, against the first delimiting wall under the impact of the fastening hooks or lugs.

The edge region engaging over the device furthermore has a protective effect against objects, which are placed on the shelf or which are inserted or removed, respectively, via the front edge of the shelf.

The angle as well as the dimensions of the second delimiting wall are thus preferably selected or adapted to one another, respectively, so that the electronic device can be contacted securely on or at the front wall thereof, respectively, with the edge region of the support device, and can thus be held in position.

The second delimiting wall does not need to run largely linearly and have a constant cross section. In the case of embodiments with more complex shapes of the second delimiting wall, the angle can be understood as that angle between the plane spanned by the first delimiting wall and the plane between the line of intersection of the first delimiting wall and the second delimiting wall and the edge region of the second delimiting wall.

A further aspect of the invention relates to the correct alignment of the electronic device during insertion into the support device. To ensure this, it proved advantageous that the first delimiting wall of the support device, in particular in a region spanned by the conductor support, comprises a structure of delimiting wall ribs and delimiting wall gorges located therebetween, which are provided for cooperating with a structure of housing ribs and housing gorges located therebetween of the housing of the device for the purpose of establishing a target orientation of the electronic device in the case of an insertion of the electronic device into the support device as intended. On the housing, the electronic device also comprises a structure of housing ribs and housing gorges located therebetween, which are provided for cooperating with delimiting wall ribs and delimiting wall gorges located therebetween of the first delimiting wall for the purpose of establishing said target orientation of the electronic device in the case of an insertion of the electronic device into the support device as intended.

The structures advantageously run in a straight line and extend at a right angle with respect to the longitudinal extension of the support device on the one hand or at a right angle with respect to the course of the conductor support groove on the other hand, respectively.

During insertion of the electronic device into the support device, these structures, which are adapted to one another, effect the establishment of a target orientation of the electronic device at the support device. Faulty contacting of the conductor tracks, which could optionally lead to malfunctions or even to short-circuits between the conductor tracks, are thus reliably avoided.

The length of the structures defines that position along the insertion movement, starting at which the target orientation is established. Due to the fact that the conductor tracks extend along the conductor support, it proved particularly advantageous that the length of the structures, measured at the dimension of the conductor support, orients itself along the direction normally to the longitudinal extension of the conductor support and parallel to the plane of the first delimiting wall. This should be provided as minimum dimension, in order to already establish the target orientation when bringing the electronic device close to the conductor support or only when the conductor support is touched for the first time by the electronic device.

The width of the structures preferably corresponds essentially to the grid dimension of the recesses along the longitudinal extension of the support device.

Lastly, it should also be mentioned that in a preferred embodiment, the recesses as well as the material webs of the support device located therebetween have identical widths, which correspond exactly to the grid dimension, so that a periodic sequence of recesses and material webs results along the longitudinal extension of the support device.

The support device as a whole can thus be embodied in a more compact manner, so that it covers a smaller viewing area in front of the products or the shelf base, respectively. Such a narrower appearance does not only make the system appear to be of high quality, but also provides for a better look at the goods, which are located behind the support device.

These and further aspects of the invention follow from the below-discussed figures.

### BRIEF DESCRIPTION OF THE FIGURES

The invention will be described in more detail once again below with reference to the enclosed figures on the basis of exemplary embodiments, to which the invention is not limited, however. Identical components are thereby provided with identical reference numerals in the various figures. Schematically:

FIG. 1 shows a support device according to the invention, embodied as shelf rail in cross section, and an electronic display unit according to the invention positioned thereon,

FIG. 2 shows the electronic display unit fastened to the shelf rail,

FIG. 3 shows a rear view of a region of the shelf rail comprising recesses in a grid,

FIG. 4 shows a rear view of the electronic display unit according to a first exemplary embodiment,

FIG. 5 shows a side view of the electronic display unit,

FIG. 6A shows an electrical contacting of contacts of the electronic display unit and wires of the shelf rail,

FIG. 6B shows a metallic contact band of the electronic display unit,

FIG. 7 shows an exemplary embodiment of a shelf rail comprising support web,

FIG. 8 shows a further exemplary embodiment of a shelf rail comprising support web,

FIG. 9 shows a supply means laterally inserted into the shelf rail comprising largely exposed housing,

FIG. 10 shows the electronic connection between the shelf rail and the supply means in a view without its housing,

FIG. 11 shows a battery unit magnetically attached to the shelf for supplying the electronics of the shelf rail,

FIG. 12 shows a combined view of shelf rail and two display units,

FIG. 13 shows a rear view of the shelf rail comprising inserted supply means,

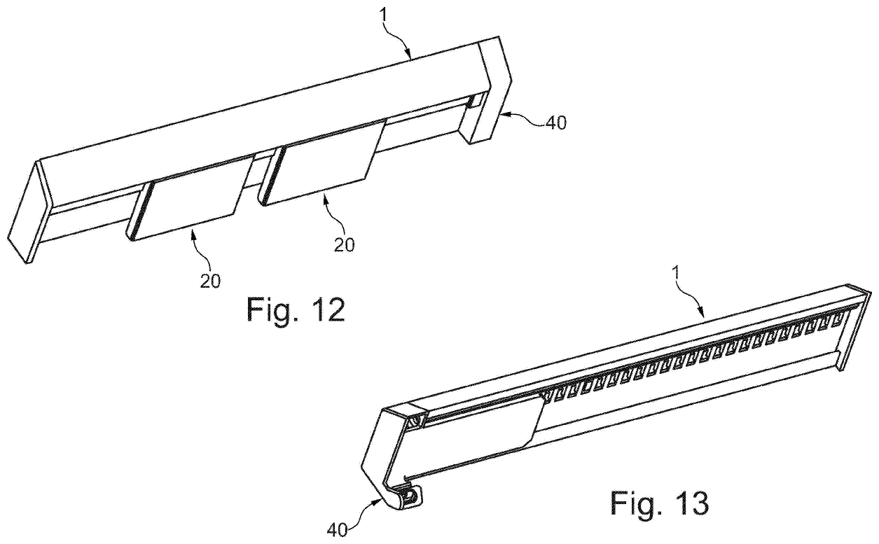

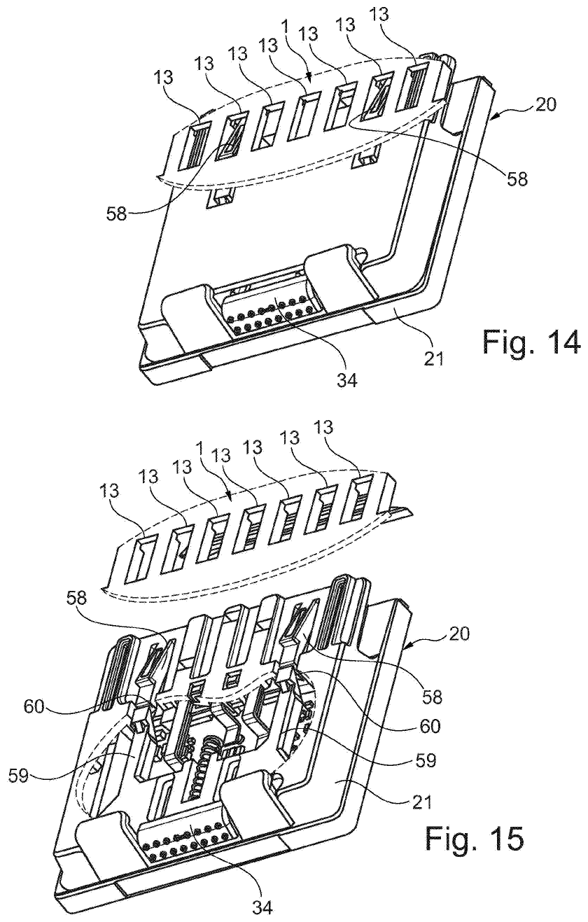

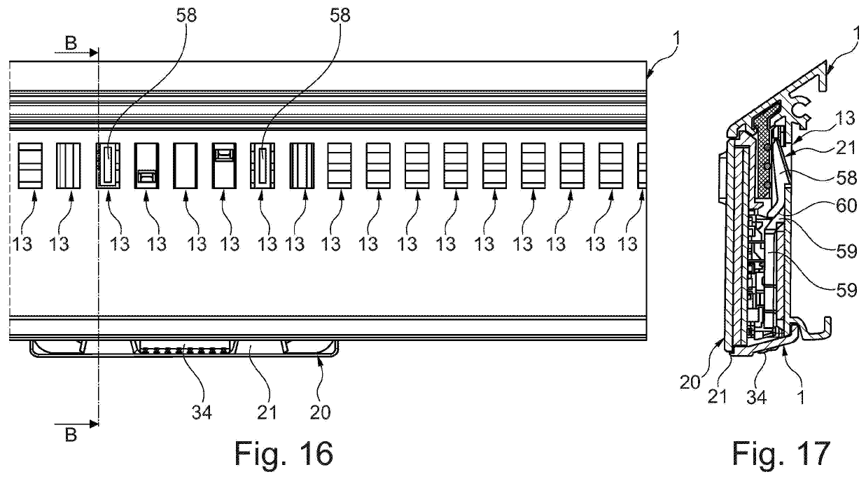

FIGS. 12-13 show details of a second embodiment of the display unit,

FIGS. 14-17 show a second embodiment of the display means.

### DESCRIPTION OF THE EXEMPLARY EMBODIMENTS

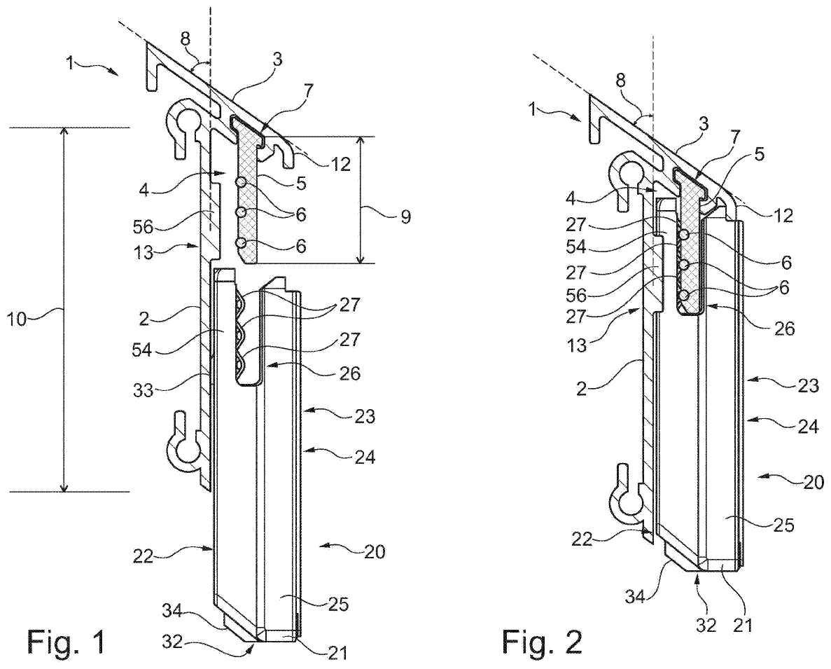

FIG. 1 shows a support device, realized as shelf rail 1, and a device, which is compatible with the shelf rail 1, realized, for example, as an electronic display unit 20 in a lateral viewing direction, wherein the shelf rail 1 can be seen in a section along a sectional surface adjacent to the display unit.

The shelf rail 1 comprises a first delimiting wall 2 (reference wall 2), which is illustrated vertically in the illustration.

On its upper end, the first delimiting wall or reference wall 2, respectively, merges into a second delimiting wall 3. In this exemplary embodiment, the second delimiting wall 3 and the reference wall 2 are made of steel in one piece.

Between the reference wall 2 and the second delimiting wall 3, there is located a receiving region 4, which is delimited on two sides by means of these walls 2 and 3, for receiving the display unit 20.

Measured on the side of the display unit 20, thus measured in the spatial region of the receiving region 4, an acute angle 8 with approximately 53° is formed between the reference wall 2 and the second delimiting wall 3.

The second delimiting wall 3 comprises a receiving shaft 7, into which a conductor support 5 is inserted, which is embodied as conductor support plate. On that side, which is inserted into the receiving shaft 7, the conductor support 5 is adapted to the shape of the receiving shaft 7, is thus formed essentially in a T-shaped manner. In the receiving shaft 7, the conductor support 5, normally on the image plane of FIG. 1, can be shifted out of or into said image plane, respectively, in order to insert said conductor support there or also to remove it from there.

The conductor support 5 supports three conductor tracks 6. The conductor tracks 6 are in each case made of a single-core copper wire 6 and are embodied in an insulation layer-free manner. More than 50% of the cross section of the wires 6, approximately two thirds of the radial dimension, are embedded in the conductor support 5. That wire 6, which is located closest to the second delimiting wall 3, is thereby the power supply line, the central conductor track 6, the signal supply line, and the conductor track 6, which is located farthest away from the second delimiting wall 3, is the reference potential line. The wires 6 are arranged on that side of the conductor support 5, which faces the reference wall 2.

The conductor support 5 and the reference wall 2 in each case have a first dimension (longitudinal extension), which represents the linear measure, measured out of the image plane or into the image plane, respectively, wherein both are of identical size in this exemplary embodiment and are, for example, approximately 1.5 m long. However, other lengths for the shelf rail 1 can also be provided.

The conductor support 5 has a second dimension 9 (height), which represents the vertical expansion of the conductor support 5 in FIG. 1. Corresponding thereto, the reference wall 2 has a third dimension 10 (height), which specifies the vertical expansion of the reference wall 2 in FIG. 1. In this exemplary embodiment, the second dimension 9 of the conductor support 5 is approximately 40% of the third dimension 10 of the reference wall 2. In the case of this exemplary embodiment, the second dimension 9 is, for example, approximately 3 cm.

In this exemplary embodiment, the conductor support 5 is made of insulating polypropylene by means of injection molding process, whereby the wires 6 have already been embedded during the production process of the conductor support 5.

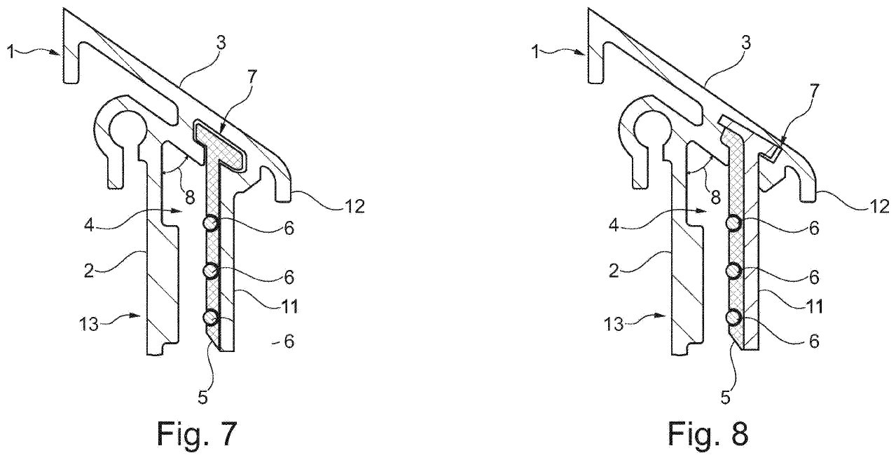

In the present case, the conductor support 5 is arranged in a freestanding manner. In contrast, exemplary embodiments comprising a support web 11 are illustrated in FIGS. 7 and 8. In FIG. 7, the support web 11 is connected by means of a substance-to-substance bond to the second delimiting wall 3, and, together, the reference wall 2, the second delimiting wall 3, and the support web 11 form a component part. They are thus formed in one piece. In FIG. 8, the support web 11 is embodied as independent part and is formed to be received or pushed into the receiving shaft 7, respectively, together with the conductor support 5.

As can be seen in FIGS. 1, 2, 7, and 8, the second delimiting wall 3 comprises, on the end side, an edge region 12, which is formed in a lug-shaped or hook-shaped manner, respectively, and which, when the display unit 20 is inserted, prevents that the latter can be moved away from the reference wall 2 in the normal direction, based on the reference wall 2.

The reference wall 2 comprises recesses 13 arranged in the grid, which are illustrated in FIG. 3 and which serve for fastening the display unit 20, which will be discussed below.

In FIG. 1, the display unit 20 is positioned so that it can be inserted with a rectilinear movement parallel to the reference wall 2 into the shelf rail 1 from below in the direction of the second delimiting wall 3.

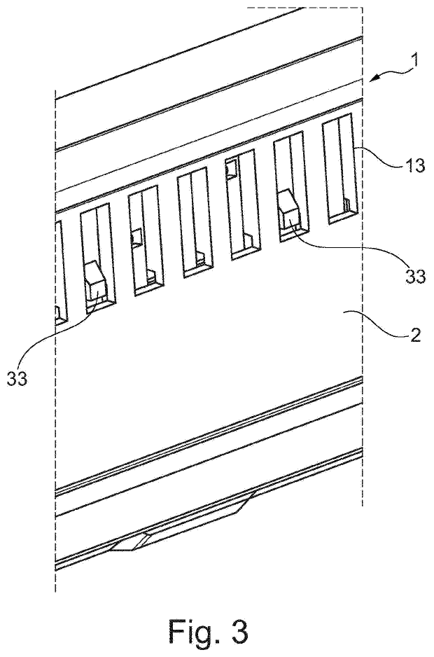

The display unit 20 comprises a housing 21 comprising a rear wall 22. The rear wall 22 thereby represents that part of the housing 21, which, as can be seen in FIGS. 2, is located closest to the reference wall 2 when inserted in the shelf rail 1. A front wall 23, which comprises a screen 24, is located on the side opposite the rear wall 22. On its upper end, the front wall 23 comprises a step, which is formed for receiving the edge region 12 of the shelf rail 1. Between the front wall 23 and the rear wall 22, the housing 21 is formed by a side wall 25. The side wall 25, which runs along the top side of the display unit 20, comprises a conductor support groove 26, the vertical walls of which run essentially parallel to the rear wall 22. The conductor support groove 26 is provided for receiving the conductor support 5 and is dimensioned so as to be adapted to its dimensions.

In the conductor support groove 26, the housing 21 comprises housing openings on the rear wall side, through which contacts 27 protrude out of the housing 21 into the conductor support groove 26. The contacts 27 are realized by means of a group of metallic contact bands 27.

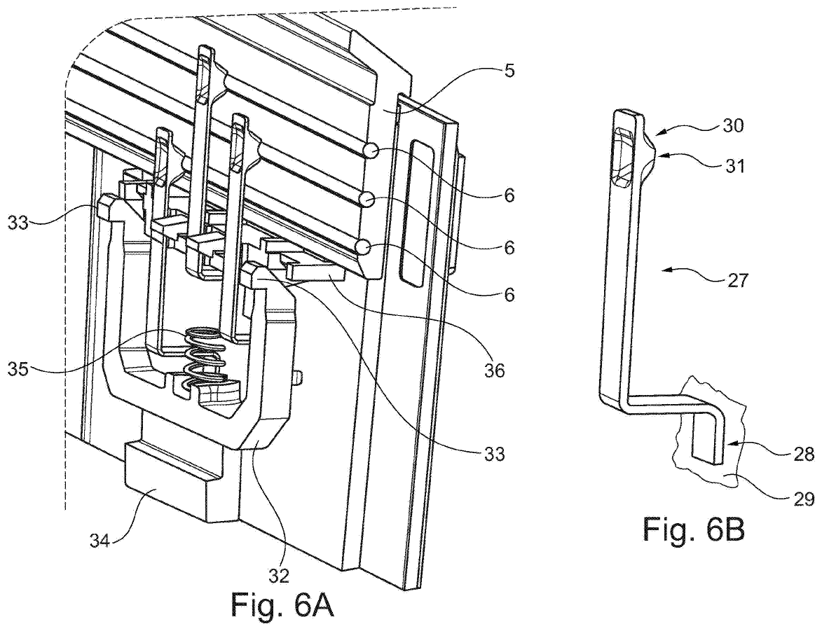

The metallic contact bands 27 are illustrated in more detail in FIG. 6A and FIG. 6B. FIG. 6B shows the setup or the shape, respectively, of a contact band 27, which comprises a first end portion 28, which is soldered to a device electronics or display electronics 29, respectively, which is only illustrated in sections. The contact band 27 furthermore comprises a second end portion 30, which is formed or shaped, respectively, for the contacting with one of the wires 6, as it is illustrated in FIG. 6A.

The second end portion 30 comprises a raised shape 31 as contact zone. This raised shape 31 is also that part of the metallic contact bands 27, which can be seen in FIGS. 1 and 2 in the lateral view of the display unit.

As can be seen in FIG. 6A or 6B, respectively, the two end portions 28, 30 are arranged in parallel, but offset in this exemplary embodiment, so that the contact band 27 forms a step. This step provides for a larger spring deflection and a distribution of the bending stress on the resilient material. At the same time, said step overcomes the distance (level difference) between the plane of the display electronics 29 and the plane of the contacting, which is spanned by the wires 6.

For the sake of clarity, a plurality of the components of the electronic display unit 20 are not illustrated in FIG. 6A in order to clear the view onto a fastening mechanism 32. The fastening mechanism 32 is embodied in one piece and comprises two fastening hooks 33 and a button 34 connected thereto. The fastening mechanism 32 is moreover in contact with a spring element 35, which is formed as helical screw.

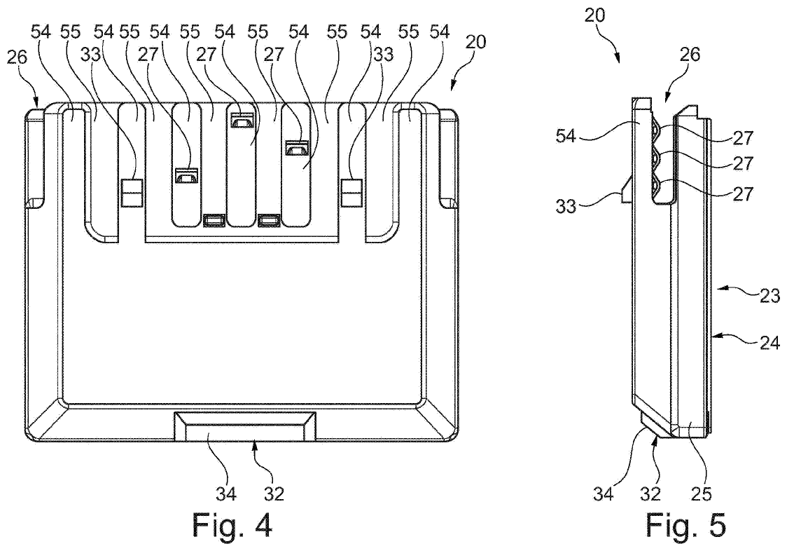

As can be seen in FIGS. 4 and 5, the rear wall 22 comprises fastening housing openings, through which the fastening hooks 33 protrude.

FIG. 6A furthermore shows a housing connecting element 36, which connects both housing halves (the front and the rear housing half of the housing 21) to one another by means of plug connection or clamp connection, respectively.

The spring element 35 rests with the side, which is illustrated freely in FIG. 6A, on the housing 21 with prestress. The spring element 35 thus acts between the fastening mechanism 32 and the housing 21. It thus pushes the fastening mechanism 32 and thus the fastening hooks 33 and the button 34 downwards parallel to the rear wall 22 in the orientation of FIG. 6A away from the conductor support groove 26.

If, starting at the arrangement illustrated in FIG. 1, the electronic display unit 22 is now pushed parallel to the reference wall 2 in the direction of the second delimiting wall 3, so that the display unit 22 is finally positioned and fixed in the shelf rail 1 as illustrated in FIG. 2, the end portions 30 of the contact bands 27 touch the wires 6.

It should also be mentioned here that, on this free end, the conductor support 5 comprises a bezel, which is oriented towards the first delimiting wall or the reference wall 2, respectively, and which ensures that the raised shape 31 of the contact bands 27 is raised to the plane of the wires 6 without any problems when the display unit 22 is inserted into its target position at the shelf rail 1 from below. Each contact band 27 is thereby prestressed. During the further insertion into the shelf rail 1, at least two of the three contacts slide with their raised contact zones beyond two of the wires 6, until all three contacts ultimately reach with their raised contact zones the respective wire 6 to be contacted and are lifted off the conductor support 5 there, thus the prestressing is intensified, which contributes to an optimal electronic contacting of the wires 6.

It should furthermore be mentioned that during the insertion of the display unit 20 into the shelf rail 1, the fastening hooks 33 slide along the reference wall 2 until they reach the recesses 13 of the reference wall 2, in which they automatically interlock. It can be seen in FIG. 3, how the display unit 20 is currently being inserted into the shelf rail 1 or is removed from it, respectively, because the fastening hooks 33 are slightly spaced apart from the lower edges of the recesses 13. In the inserted state, they touch the lower edge of the recesses 13, thus that edge, which is spaced apart farthest from the second delimiting wall 3. The recesses 13 illustrated in FIG. 3 are approximately as wide as or slightly wider than, respectively, the fastening hooks 33. This creates a fine, but well-defined grid, so that the electronic display units 20 can no longer be shifted continuously along the shelf rail 1, but can be positioned at clearly defined points.

As can be seen in FIG. 6A, the spring element 35 acts on the housing 21 on the one hand and on the fastening mechanism 32 on the other hand in the interior of the display unit 1, so that the fastening hook 33 is pushed against the lower edge of the recess 13 of the rear wall 2, whereby the electronic display unit 20 is pushed upwards in the direction of the second delimiting wall 3. As can be seen in FIG. 2, the lower edge or side, respectively, of the conductor support 5, thus that side of the conductor support 5, which is spaced apart farthest from the second delimiting wall 3, rests at the lowest point in the conductor support groove 26, so that a clearly defined mechanical contact point is created between the electronic display unit 20 and the shelf rail 1. Two additional ones of such defined contact points are located between the edge region 12 and the upper edge of the front wall 23 and between the reference wall 2 and that region of the rear wall 22, which runs in the region of the wires 6. In the assembled state, these defined contact points provide for an unambiguous specification of the body-fixed points of the electronic display unit 20 with respect to the shelf rail 1 and vice versa. During the insertion of the display unit 20 into the shelf rail 1, the display unit 20 is thus received and aligned in the shelf rail 1, always in the same manner or always optimally, respectively, in a reproducible and in an automatic manner due to the spring effect of the spring element 35.

If the button 34 is now pushed, the connection of the fastening hooks 33 and of the reference wall 2 is released, whereupon the electronic display unit 20 can be removed downward out of the shelf rail 1, optionally also inclined forward after a lowering by the dimension of the conductor support 5. In response to actuation of the button 34, the fastening hook 33 moves to the top on the one hand, thus in the direction of the second delimiting wall 3, and into the electronic display unit 20 on the other hand, thus away from the reference wall 2, whereby the display unit 20 is released for the removal out of the shelf rail 1.

FIG. 4 shows the electronic display unit 20 from the rear, thus looking at the rear wall 2. In this view, the positions of the raised shape 31 of the metallic contact bands 27 are visible through housing openings of the rear wall 2. They can be electronically contacted there, so that the display unit 20 can also be operated or tested, respectively, outside of the shelf rail 1.

It can furthermore be seen in FIG. 4 that the rear wall 22 comprises raised housing ribs 54, which are arranged in said grid, comprising housing gorges 55 located therebetween. These structures 54 and 55 are formed of identical width and in a straight manner and run strictly at the angle of 90°, based on the longitudinal extension of the conductor support groove 26, thus in the direction from the upper side wall 25 to the lower side wall 25. In the region parallel to the conductor support 5, the shelf rail 1 also comprises, on its first delimiting wall or reference wall 2, respectively, delimiting wall ribs 56 comprising delimiting wall gorges 57 located therebetween. These structures 56 and 57 are formed of identical width and in a straight manner and run strictly at an angle of 90°, based on the longitudinal extension of the shelf rail 1.

In contrast to the structure 54 and 56 of the housing 25, the structures 56 and 57 of the shelf rail 1 are in each case offset by one grid unit, so that the housing ribs 54 can be inserted into delimiting wall gorges 57, while delimiting wall ribs 57 can be inserted into housing gorges 55. The position of the housing opening for the fastening hooks or lugs 33 is preferably always located at the position of a housing rib 54.

The structures 54-57 ensure that the display unit 20 is aligned as exactly as possible at a right angle (90°) to the longitudinal extension of the conductor support 5 at an early stage in response to the insertion into the shelf rail 1, in order to avoid contacting errors, optionally also short-circuits, between the wires 6, which could appear if a display unit 20 is inserted in a slanted manner.

FIG. 5 shows a side view of the electronic display unit 20, wherein, in contrast to FIGS. 1 and 2, the display unit 20 is illustrated without the shelf rail 1, thus the fastening hooks 33 are also visible.

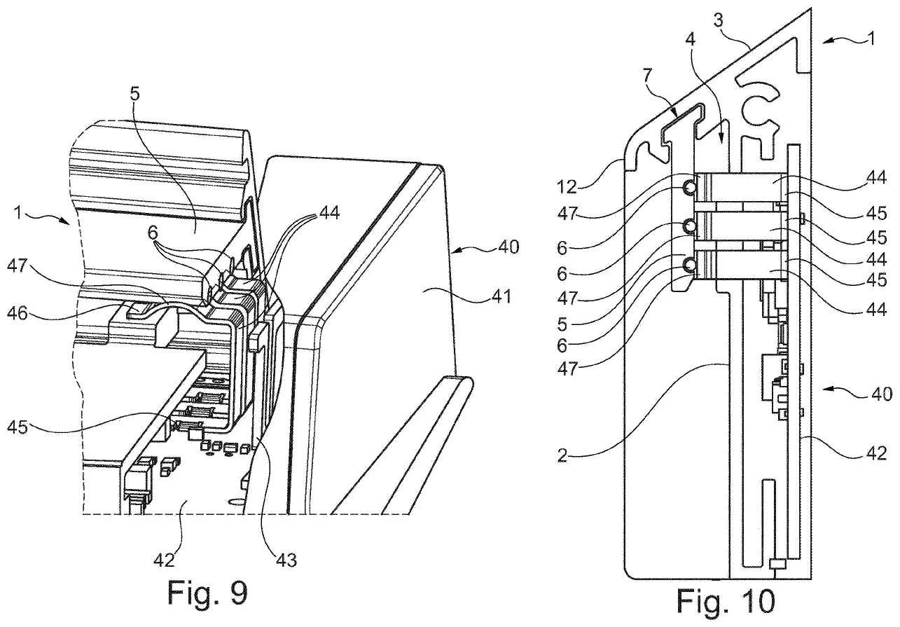

FIG. 9 shows the supply means 40, which is inserted into the lateral end portion of the shelf rail 1 and is coupled to the shelf rail 1 there.

The supply means 40 comprises a housing part 41, which is illustrated in a largely exposed manner in this view, in order provide a view onto the components located therein. The supply means 40 comprises a supply electronics 42, which also includes an antenna 43, wherein the supply electronics 42 is formed to exchange and process radio-based data with an access point with the help of the antenna 43, and to communicate in a wired manner with the devices on the shelf rail 1, or to control them as well as supply them with electric power for the operation thereof.

The supply electronics 42 comprises contacts, which—similarly to the contacts of the display means 20—are realized as a second group of metallic contact bands 44. Each of these contact bands 44 has a first end portion 45, which is soldered to the supply electronics 42, and has a second end portion 46, which has an arc shape 47 as contact zone.

The first end portion 45 and the second end portion 46 are arranged essentially parallel to one another and are connected to one another so that each contact band 44 assumes a C-shape or U-shape, respectively. The lateral edge of the shelf rail 1 is thus encompassed, namely without the latter being touched outside of the desired contact region.

The contact bands 44 are formed resiliently and push with the arc shape 47 against the wires 6 with a prestress, which ensures a defined contacting force, wherein each contact band 44 is assigned to exactly one wire 6.

The housing part 41 is open on one side (on the left side in the perspective of FIG. 9), so that the supply means 40 can be inserted into the shelf rail 1 (from the right in the perspective of FIG. 9), wherein the contact bands 44 slide along the wires 6 with the arc shape 47 and establish an electrically conductive connection. The supply electronics 42 is pushed behind the reference wall 2 of the shelf rail 1, where it is surrounded and protected by parts of the shelf rail 1. The housing part 41 comprises defined contact zones, with which it is in mechanical contact with the shelf rail 1, in order to ensure a precise positioning of the supply means 40 with respect to the shelf rail 1.

FIG. 10 shows the supply means 40, which is inserted into the shelf rail 1, wherein, for the sake of clarity, the illustration of some components, such as, for instance, the housing part 41 and the antenna 43, was forgone.

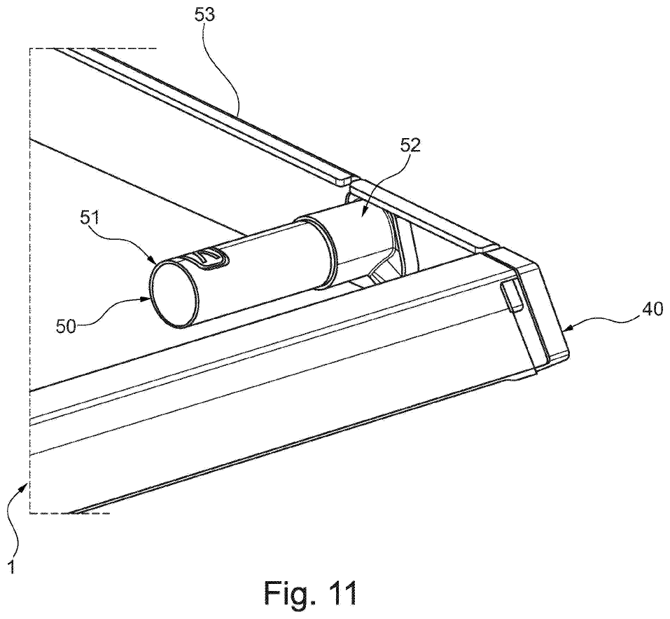

FIG. 11 shows a re-chargeable accumulator unit 50, which comprises an accumulator (or also a re-chargeable battery) 51 and a fastening element 52, and which is connected to the supply means 40 by means of a cable (not illustrated). The fastening element 52 is realized with the help of three magnets, which are arranged in a triangle, and comprises a contact surface for the planar placement onto a lateral shelf part 53 of the shelf, which is made of steel. The shelf base was removed from this shelf in order to clear a view onto the accumulator unit 50.

The shelf rail 1 is mounted to the lateral shelf part 53 at a right angle.

During the maintenance, the entire accumulator unit 50 can be removed and replaced easily thanks to the magnetic connection.

In FIG. 14, a section of the shelf rail 1 and the display unit 20 can be seen from its rear side. These two elements 1 and 20 are illustrated separately from one another in FIG. 15, whereby the housing 21 is also illustrated here so as to be exposed on its rear wall, clearing the view onto the interior of the display unit 20. In FIG. 16, the shelf rail 1 can be seen from its rear side with inserted display unit 20, and FIG. 17 shows a section along the sectional line BB according to FIG. 16. It should also be mentioned here that, for the sake of clarity, some of the reference numerals are not entered in these figures.

In contrast to the display unit 20 illustrated in the preceding figures, a multi-piece formation of the fastening means is used here. In the present case, the housing 21 comprises two fastening hooks or lugs 58, which are realized as part of the housing 21. These fastening hooks or lugs 58 engage with the recesses 13 of the shelf rail 1, as can be seen clearly in FIGS. 14, 16, and 17.

In FIG. 15, the button 34 is can be seen in detail with its two actuating appendages 59, which are provided for actuating the two fastening hooks or lugs 58. It can furthermore be seen in FIG. 17, how the actuating appendages 59 cooperate with the fastening hooks or lugs 58, namely via a plane 60, which is oriented in an inclined manner with respect to its longitudinal extension, thus an inclined plane. (see also FIG. 17), which is formed at the respective component part ends, so that the component part ends can slide along one another when the button 34 is actuated. In response to actuation of the button 34, the two fastening hooks or lugs 58 are pushed into the interior of the housing by means of the longitudinal movement of the actuating appendages 59, and the connection between the shelf rail 1 and the display unit 20 is released.

In conclusion, it is pointed out once again that the figures, which are described above in detail, are only exemplary embodiments, which can be modified in many different ways by the person of skill in the art, without leaving the scope of the invention. For the sake of completeness, it is also pointed out that the use of the indefinite article “a” does not rule out that the respective features can also be present more than once.

1. A support device (1), preferably realized as shelf rail, for mechanically fastening an electronic device (20), particularly preferably for fastening an electronic display unit, wherein the support device (1) comprises:
a first delimiting wall (2), in particular a reference wall (2) defining a reference or positioning plane, respectively, on the or adjacent to which the electronic device can be positioned, in particular with its rear wall (22), on the support device (1), and
a second delimiting wall (3), which is oriented at an angle (8) to the first delimiting wall (2), wherein the first delimiting wall (2) and the second delimiting wall (3) delimit, in particular only on two sides, a receiving region (4) for receiving the electronic device (20), and
a conductor support (5), which supports conductor tracks (6) for the electronic supply of the electronic device (20),
characterized in that
the conductor support (5) protrudes into the receiving region (4) at a distance from the first delimiting wall (2), starting at the second delimiting wall (3), in particular parallel to the first delimiting wall (2).

2. The support device (1) according to claim 1, wherein the conductor support (5) is formed as conductor support plate.

3. The support device (1) according to claim 2, wherein the
conductor support plate comprises a first dimension, which is measured along the longitudinal extension of the support device (1), and comprises a second dimension (9), which, in the plane of the conductor support plate, is measured in a normal manner at the first dimension of the conductor support plate, wherein the second dimension of the conductor support plate corresponds to 20% to 40% of the corresponding dimension (10) of the first delimiting wall (2).

4. The support device (1) according to claim 1, wherein the conductor support (5) comprises three pieces of the conductor tracks (6), which are preferably formed at a single side surface of the conductor support (5) and/or which run parallel to one another along the longitudinal extension of the support device (1).

5. The support device (1) according to claim 1, wherein the conductor tracks (6) are embodied as wires, which partially protrude beyond the outer surface of the conductor support (5).

6. The support device (1) according to claim 1, wherein the conductor tracks (6) are arranged on that side of the conductor support (5), which faces the first delimiting wall (2).

7. The support device (1) according to claim 1, wherein the second delimiting wall (3) comprises a receiving shaft (7), which is provided for receiving, in particular for laterally insertable receiving, the conductor support (5), and the conductor support (5) comprises a shape, which corresponds to the shape of the receiving shaft, in particular a T-shape or an upside down L-shape, and is inserted into the receiving shaft (7).

8. The support device (1) according to claim 1, wherein the second delimiting wall (3) comprises a support web (11), which extends essentially along the conductor support (5) and mechanically supports the latter.

9. The support device (1) according claim 1, wherein the conductor support (5) is made of plastic.

10. The support device (1) according to claim 1, wherein the first delimiting wall (2) and the second delimiting wall (3), in particular also the support web (11) according to claim 7, are formed in one piece, in particular made of steel.

11. The support device (1) according to claim 1, wherein the first delimiting wall (2) comprises recesses (13), which are arranged along its longitudinal extension in the grid, in particular openings, which pass through the first delimiting wall (2), and which are intended for the non-positive and/or positive coupling with fastening means of an electronic device.

12. The support device (1) according to claim 1, wherein with respect to that side of the first delimiting wall (2), which is oriented towards the receiving region (4), an acute angle (8), in particular an angle in a range of from 65° to 85°, is formed between the first delimiting wall (2) and the second delimiting wall (3).

13. (canceled)

14. (canceled)

15. (canceled)

16. A supply means (40) for a support device (1), in particular realized as shelf rail, for the electric supply of an electronic device (20), which can be supported by means of the support device (1), particularly preferably of an electronic display unit (20), wherein the supply means (40) is formed in such a way that it can be coupled to a side or end portion, respectively, of the support device (1), which side or end portion, respectively, is formed or provided, respectively, for receiving the supply means (40),
wherein the supply means (40) comprises:
a supply electronics (42) and
contacts (44) connected to the supply electronics (42) for establishing an electrically conductive connection with conductor tracks (6) arranged on a conductor support (5) of the support device (1),
characterized in
that the contacts (44) are realized by means of a first group of metallic contact bands (44), wherein each contact band (44) comprises a first portion, preferably first end portion (45), which first portion (45) is connected to the supply electronics (42), and comprises a second portion, preferably second end portion (46), which second portion (46) is intended for contacting the conductor tracks (6) of the conductor support (5), and wherein each contact band (44) is formed in a curved or angled manner, preferably at least in an L-shaped, particularly preferably in a U-shaped manner.

17. The supply means (40) according to claim 16, wherein each contact band (44) comprises, on its second portion (46), an arc shape (47), which is provided for the direct contact with one of the conductor tracks (6).

18. (canceled)

19. An electronic device (20), in particular electronic display unit (20), which comprises a housing (21) comprising a rear wall (22), a front wall (23), in particular comprising a screen (24), and a side wall (25) running between the rear wall (22) and the front wall (23), wherein the side wall (25) comprises a conductor support groove (26), which runs essentially parallel to the rear wall (22), and which is intended for receiving a conductor support (5) of a support device (1), wherein the conductor support (5) comprises conductor tracks (6) for the electronic supply of the electronic device (20), in particular of the display unit (20).

20. The electronic device (20) according to claim 19, which comprises contacts (27) for establishing an electrically conductive connection with the conductor tracks (6) of the conductor support (5), wherein that housing part, which forms the conductor support groove (26), comprises first housing openings, through which the contacts (27) protrude out of the housing (21).

21. The electronic device (20) according to claim 20, wherein the first housing openings are realized on that side of the conductor support groove (26), which is closest to the rear wall (22).

22. The electronic device (20) according to claim 20, wherein one of the housing openings in each case corresponds to the position of exactly one of the conductor tracks (6), when the conductor support (5) is inserted into the conductor support groove (26) as intended.

23. The electronic device (20) according to claim 20, wherein the electronic device (20) comprises a device electronics (29) and wherein the contacts (27) are realized as a second group of metallic contact bands (27), wherein each contact band (27) comprises a first portion, preferably first end portion (28), which first portion (28) is connected to the device electronics (29), and comprises a second portion, preferably second end portion (30), which second portion (30) is intended for contacting the conductor tracks (6) of the conductor support (5), wherein the second group of metallic contact bands (27) is embodied as spring elements, wherein each contact band (27) is preferably formed in a curved or angled manner, in particular in a step-shaped manner.

24. (canceled)

25. (canceled)

26. (canceled)

27. (canceled)

28. (canceled)

29. A system, which comprises at least one support device (1) according to the invention according to claim 1, a supply means (40) according to claim 16 coupled thereto, and at least one electronic device (20), in particular electronic display device (20), according to one of claims 19-28, which is supported by the support device (1).
